(19) United States
(12) Patent Application Publication
(10) Pub. No.: US 2020/0185344 A1
(43) Pub. Date: Jun. 11, 2020

(54) CHIP PACKAGE STRUCTURE

(71) Applicant: Industrial Technology Research Institute, Hsinchu (TW)

(72) Inventors: Wei-Yuan Cheng, Hsinchu County (TW); Chen-Tsai Yang, Taoyuan City (TW)

(73) Assignee: Industrial Technology Research Institute, Hsinchu (TW)

(21) Appl. No.: 16/459,639

(22) Filed: Jul. 2, 2019

(30) Foreign Application Priority Data
Dec. 11, 2018 (TW) 107144647

(51) Int. Cl. H01L 23/00; H01L 27/02; H01L 23/31

(52) U.S. Cl. CPC H01L 24/08; H01L 2224/0233; H01L 23/3107; H01L 27/0266

(57) ABSTRACT

A chip package structure includes a redistribution circuit layer, at least one chip and an encapsulation material. The redistribution circuit layer includes at least one transistor. The chip is arranged on the redistribution circuit layer and is electrically connected to the redistribution circuit layer. The encapsulation material is arranged on the redistribution circuit layer and covers the at least one chip. When the chip package structure includes one or more chips, a position of the chip is taken as a reference for arrangement of a position of the at least one transistor.

### CROSS-REFERENCE TO RELATED APPLICATION

This application claims the priority benefit of Taiwan application no. 107144647, filed on Dec. 11, 2018. The entirety of the above-mentioned patent application is hereby incorporated by reference herein.

### TECHNICAL FIELD

The technical field relates to a chip package structure.

### BACKGROUND

In a chip package structure, to provide an electrostatic discharge protection function of a chip or a system, under the condition that the size of the chip package structure is not increased, the electrostatic discharge protection function can be integrated into the chip or system package structure. For example, a transistor with the electrostatic discharge protection function can be integrated in the system package structure, and furthermore, a transistor with a switch control function can also be integrated into the system package structure.

In a chip package structure with an encapsulation material and a redistribution circuit layer (RDL), a transistor with the electrostatic discharge protection function or other functions can be arranged in the redistribution circuit layer. However, after a support substrate is removed, the transistor loses the support force of the support substrate and becomes abnormal or even fails due to the mechanical stress generated by the encapsulation material.

### SUMMARY

A chip package structure according to the embodiments of the disclosure includes a redistribution circuit layer, a first chip, a second chip and an encapsulation material. The redistribution circuit layer includes at least one transistor. The first chip and the second chip are arranged on the redistribution circuit layer and are electrically connected to the redistribution circuit layer. The encapsulation material is arranged on the redistribution circuit layer, has a first surface away from the redistribution circuit layer and covers the first chip and the second chip, orthogonal projections of the first chip and the second chip on the first surface are respectively a first projection and a second projection, the first projection and the second projection respectively have an edge a11 and an edge a12 close to each other, and a distance between a center of the edge a11 and a center of the edge a12 is D₁. A position of an orthogonal projection of the at least one transistor on the first surface meets one of the following conditions (1) and (2): condition (1): between the edge a11 and the D₁/3 position from the edge a11; and condition (2): between the D₁/3 position from the edge a11 and the 2D₁/3 position from the edge a11.

A chip package structure according to the embodiments of the disclosure includes a redistribution circuit layer, a first chip and an encapsulation material. The redistribution circuit layer includes at least one transistor. The first chip is arranged on the redistribution circuit layer and is electrically connected to the redistribution circuit layer. The encapsulation material is arranged on the redistribution circuit layer, has a first surface away from the redistribution circuit layer, and covers the first chip. A thickness of the first chip in a direction perpendicular to the first surface is t, an orthogonal projection of the first chip on the first surface has four edges, and the four edges form a rectangle with an area A. A position of an orthogonal projection of the at least one transistor on the first surface is within a quadrangle surrounded by four straight lines respectively parallel to the four edges and with a distance t from the four edges, and the area of the quadrangle is greater than the area A.

A chip package structure according to the embodiments of the disclosure includes a redistribution circuit layer, a first chip, a second chip, a third chip, a fourth chip and an encapsulation material. The redistribution circuit layer includes at least one transistor. The first chip, the second chip, the third chip and the fourth chip are arranged on the redistribution circuit layer in an array arrangement mode and are electrically connected to the redistribution circuit layer, where the first chip and the third chip are arranged diagonally. The encapsulation material is arranged on the redistribution circuit layer, has a first surface away from the redistribution circuit layer, and covers the first chip, the second chip, the third chip and the fourth chip. Orthogonal projections of the first chip, the second chip, the third chip and the fourth chip on the first surface are respectively a first projection, a second projection, a third projection and a fourth projection, the first projection and the second projection respectively have an edge a11 and an edge a12 close to each other, a distance between a center of the edge a11 and a center of the edge a12 is D₁, the first projection and the fourth projection respectively have an edge a21 and an edge a23 close to each other, and a distance between a center of the edge a21 and a center of the edge a23 is D₂. In an arrangement direction parallel to the first projection and the second projection, the position of the orthogonal projection of the at least one transistor on the first surface meets one of the following conditions (i) and (ii): condition (i): between the edge a11 and the D₁/3 position from the edge a11; and condition (ii): between the D₁/3 position from the edge a11 and the 2D₁/3 position from the edge a11. In an arrangement direction parallel to the first projection and the fourth projection, the position of the orthogonal projection of the at least one transistor on the first surface meets one of the following conditions (a) and (b): condition (a): between the edge a21 and the D₂/3 position from the edge a21; and condition (b): between the D₂/3 position from the edge a21 and the 2D₂/3 position from the edge a21.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a cross-sectional view of a chip package structure according to a first embodiment of the disclosure.

FIG. 2 is a cross-sectional view of a chip package structure according to a second embodiment of the disclosure.

FIG. 3 is a top view of a chip package structure according to a third embodiment of the disclosure.

FIG. 4 is a schematic diagram of removing a support substrate after a chip package structure is finished according to a fourth embodiment of the disclosure.

FIG. 5 is a top view of an arrangement position of a transistor in a chip package structure according to a fifth embodiment of the disclosure.

FIG. 6A is a schematic diagram of orthogonal projections of two chips on a first surface of an encapsulation material away from a redistribution circuit layer.

FIG. 6B is a top view of an arrangement position of a transistor in a chip package structure according to a sixth embodiment of the disclosure.

FIG. 6C is a top view of an arrangement position of a transistor in a chip package structure according to a seventh embodiment of the disclosure.

FIG. 6D is a top view of an arrangement position of a transistor in a chip package structure according to an eighth embodiment of the disclosure.

FIG. 6E is a top view of an arrangement position of a transistor in a chip package structure according to a ninth embodiment of the disclosure.

FIG. 7A and FIG. 7B are respectively top views of arrangement positions of transistors in chip package structures according to a tenth embodiment and an eleventh embodiment of the disclosure.

FIG. 8A is a schematic diagram of orthogonal projections of four chips on a first surface of an encapsulation material away from a redistribution circuit layer.

FIG. 8A-1 is a schematic diagram for dividing the schematic diagram of the orthogonal projections of the four chips in FIG. 8A into a central region and peripheral regions.

FIG. 8B is a top view of an arrangement position of a transistor in a chip package structure according to a twelfth embodiment of the disclosure.

FIG. 9A to FIG. 9C are respectively top views of arrangement positions of transistors in peripheral regions of chip package structures according to a thirteenth embodiment to a fifteenth embodiment of the disclosure.

FIG. 10A to FIG. 10C are respectively top views of arrangement positions of transistors in central regions of chip package structures according to a sixteenth embodiment to an eighteenth embodiment of the disclosure.

FIG. 11A to FIG. 11G are respectively top views of arrangement positions of transistors in chip package structures according to a nineteenth embodiment to a twenty-fifth embodiment of the disclosure.

FIG. 12 is a top view of an arrangement position of a transistor in a chip package structure according to a twenty-sixth embodiment of the disclosure.

### DETAILED DESCRIPTION OF DISCLOSED EMBODIMENTS

The embodiments of the disclosure provide a chip package structure, where a transistor is arranged in a redistribution circuit layer of the chip package structure, and a position of a chip is taken as a reference for position arrangement of the transistor.

The embodiments of the disclosure provide a chip package structure, where a transistor is arranged in a redistribution circuit layer of the chip package structure, and an arrangement position of the transistor may allow the transistor to be subjected to a relatively small stress after a support substrate is removed, to maintain the function of the transistor.

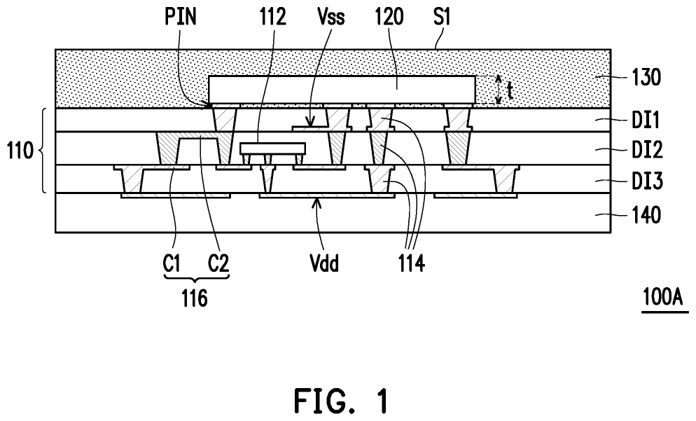

FIG. 1 is a cross-sectional view of a chip package structure according to a first embodiment of the disclosure. Referring to FIG. 1, the chip package structure 100A includes a substrate 140, a redistribution circuit layer (RDL) 110, a chip 120 and an encapsulation material 130. The redistribution circuit layer 110 is arranged on the substrate 140, and the redistribution circuit layer 110 includes at least one redistribution circuit 116, at least one transistor 112 electrically connected to the redistribution circuit 116 and a plurality of conductive vias 114 electrically connecting the redistribution circuit 116 and the transistor 112. The chip 120 and the encapsulation material 130 are arranged on the redistribution circuit layer 110, the chip 120 is electrically connected to the redistribution circuit layer 110, and the encapsulation material 130 covers the chip 120.

The substrate 140 is, for example, a glass substrate, a silicon substrate, a metal substrate, a plastic substrate, a combination thereof, or other suitable carrier substrates.

The redistribution circuit 116 includes a voltage source circuit Vdd and a ground circuit Vss, and the transistor 112 is electrically connected to the voltage source circuit Vdd, the ground circuit Vss and a pin end PIN of the chip 120. When an electrostatic discharge phenomenon occurs, the transistor 112 arranged in the redistribution circuit layer 110 can be quickly turned on, and an electrostatic discharge current is quickly released to the voltage source circuit Vdd or the ground circuit Vss, thereby effectively performing electrostatic discharge protection and preventing the chip or the circuit in the redistribution circuit layer from being damaged.

The redistribution circuit layer 110 may include a plurality of dielectric layers DI1, DI2 and DI3, and the redistribution circuit 116 may further include a first redistribution circuit C1 and a second redistribution circuit C2 which are electrically connected through a plurality of conductive vias 114. The transistor 112 may be arranged in any one of the dielectric layers DI1, DI2 and DI3. Although the transistor 112 of the present embodiment is arranged in the dielectric layer DI2, the embodiments of the disclosure do not limit the arrangement position of the transistor 112 in the dielectric layer in the redistribution circuit layer 110.

The first redistribution circuit C1, the second redistribution circuit C2 and the conductive vias 114 may be formed by the same or similar metal materials, such as copper, aluminum, silver, tin or alloys thereof, but are not limited thereto. The encapsulation material 130 includes epoxy resin and the like, and the encapsulation material 130 has a first surface S1.

The transistor 112 may include a thin film transistor (TFT). In one embodiment, the transistor 112 may be a transistor array formed by a plurality of transistors, where a plurality of first transistors in the plurality of transistors are coupled in parallel with each other, a plurality of second transistors in the plurality of transistors are coupled in parallel with each other, and the first transistors and the second transistors are configured to be turned on to release the electrostatic discharge current.

In addition to the above electrostatic discharge function, the transistor 112 integrated in the system package structure may alternatively be a transistor with a switch control function. The switch control transistor may be electrically connected to the chip 120 through the redistribution circuit 116 and/or the conductive vias 114, so that adjustment and selection of input signals can be performed for the chip 120. The disclosure does not make any limitation on the function of the transistor 112 arranged in the redistribution circuit layer 110.

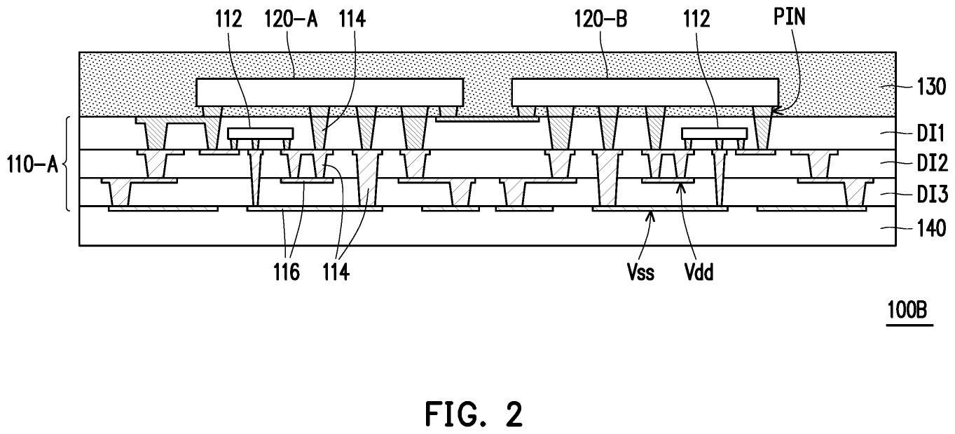

FIG. 2 is a cross-sectional view of a chip package structure according to a second embodiment of the disclosure. Referring to FIG. 2, the chip package structure 100B of the present embodiment is similar to the chip package structure 100A in FIG. 1, and therefore the components illustrated in FIG. 1 are not described herein. Referring to FIG. 2, the chip package structure 100B includes chips 120-A and 120-B arranged on the redistribution circuit layer 110A, and the chips 120-A and 120-B may be electrically connected to each other through the redistribution circuit layer 110A. An encapsulation material 130 covers the chips 120-A and 120-B. In some embodiments, the chips 120-A and 120-B may be chips with the same function. In other embodiments, the chips 120-A and 120-B may alternatively have different functions. For example, the chips 120-A and 120-B include a logic chip, a memory chip, an input/output chip and the like, but the embodiments of the disclosure are not limited thereto. Although two chips are illustrated in FIG. 2, in other embodiments, more than two chips may alternatively be arranged in the chip package structure according to design requirements. The embodiments of the disclosure do not limit the number of the chips. In addition, there is a difference from the chip package structure 100A according to the first embodiment in FIG. 1 that the transistor 112 according to the embodiment in FIG. 2 is arranged in the dielectric layer DI1.

The chip package structure 100A (or 100B) may be performed in a panel-level package (PLP) manufacturing process. In other words, after the package step is finished in the panel stage, an independent chip package structure 100A or a chip package structure 100B with a plurality of independent chip package structures 100A may be formed by cutting.

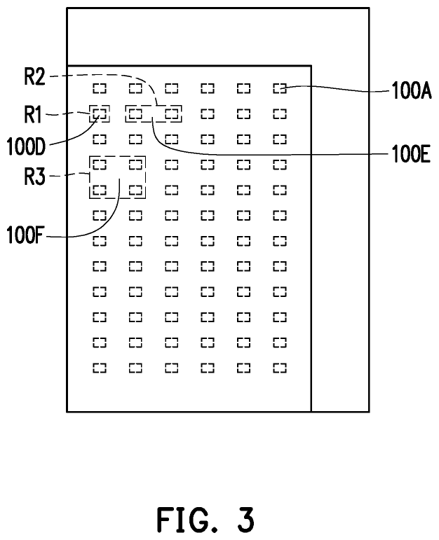

FIG. 3 is a top view of a chip package structure according to a third embodiment of the disclosure. Referring to FIG. 3, after the chip package structure is finished in a panel-level package manufacturing process, the top view of the chip package structure of the panel-level package is as shown in FIG. 3. In one embodiment, the size of a substrate may be 370×470 mm² (FIG. 3 shows only ¼ of the entire panel-level chip package structure), a plurality of chip package structures are disposed on the substrate, such as 100A, 100D, 100E and 100F, and for the cross-sectional view of the chip package structure 100A, refer to FIG. 1. A support substrate is provided firstly in the manufacturing process for the chip package structure with an encapsulation material and a redistribution circuit structure, so as to provide a sufficient support force for subsequent chip package structure manufacturing processes, and the support substrate is removed after the processes are finished. R1, R2 and R3 are respectively regions of the chip package structures 100D, 100E and 100F on the panel.

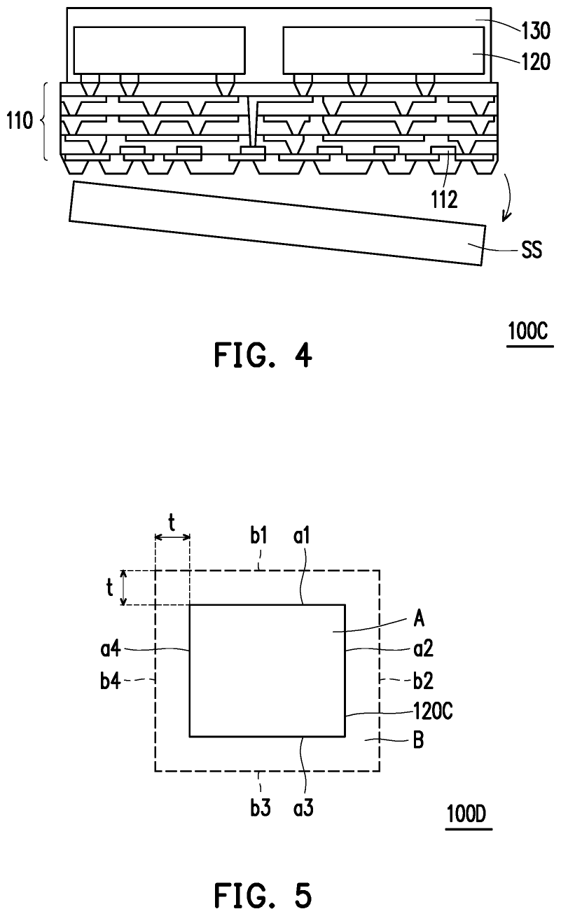

FIG. 4 is a schematic diagram of removing a support substrate after a chip package structure is finished according to a fourth embodiment of the disclosure. Referring to FIG. 4, for the description of the chip package structure 100C, refer to the aforementioned chip package structure 100A or 100B according to the first embodiment or the second embodiment, and details are not described herein. As shown in FIG. 4, a support substrate SS is provided to perform subsequent manufacturing processes of the chip package structure 100C, and the support substrate SS is removed after the processes are finished. A transistor 112 may be subjected to a mechanical stress generated by an encapsulation material 130 due to the loss of a support force of the support substrate SS. The transistor 112 is subjected to different stresses in different positions in a redistribution circuit layer 110. In other words, the magnitude of the aforementioned stress experienced by the transistor 112 is related to the position of the transistor 112 in the redistribution circuit layer 110.

The disclosure subsequently uses embodiments for describing the case that a position of a chip in the chip package structure is taken as a reference for arrangement of the transistor in the redistribution circuit layer, so that a position of the transistor can allow the transistor to be subjected to a relatively small stress.

FIG. 5 is a top view of an arrangement position of a transistor 112 in a chip package structure according to a fifth embodiment of the disclosure. Referring to FIG. 5, the present embodiment uses the chip package structure with a single chip, such as the chip package structure 100D in the region R1 in FIG. 3, for the description. For related components of the chip package structure 100D, refer to 100A in FIG. 1, and details are not described herein. Referring to FIG. 1 and FIG. 5, an encapsulation material 130 arranged on a redistribution circuit layer 110 has a first surface S1 away from the redistribution circuit layer 110, and the chip 120 has a thickness tin the direction perpendicular to the first surface S1 (referring to FIG. 1). FIG. 5 shows an orthogonal projection 120C of the chip 120 on the first surface S1, and the orthogonal projection 120C of the chip 120 on the first surface S1 has a first edge a1, a second edge a2, a third edge a3 and a fourth edge a4, and the four edges form a rectangle A with an area A_{A}. A position of an orthogonal projection of the transistor 112 in a direction perpendicular to the first surface S1 is within a quadrangle B (the quadrangle shown by dotted lines in FIG. 5) surrounded by four straight lines b1, b2, b3 and b4 respectively parallel to the four edges and with a distance t from the four edges, and an area A_{B} of the quadrangle B is greater than the area A_{A} of the rectangle A.

Still referring to FIG. 3, a single chip 120 in each chip package structure 100A of the plurality of chip package structures of the panel-level package structure may be taken as a reference for position arrangement of a transistor 112 in a redistribution circuit layer 110 according to the description in the fifth embodiment shown in FIG. 5. In other words, the orthogonal projection of the transistor 112 on the first surface S1 may be within a quadrangle B corresponding to each chip.

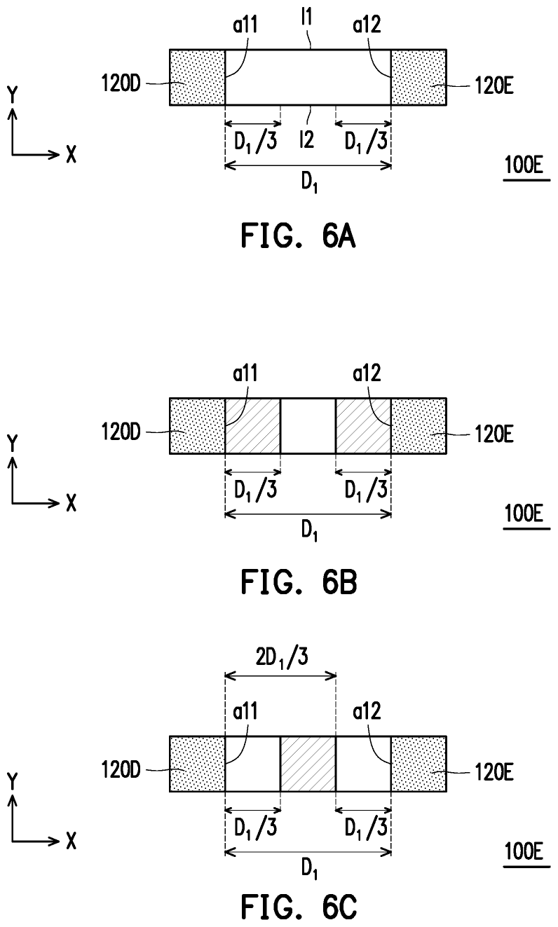

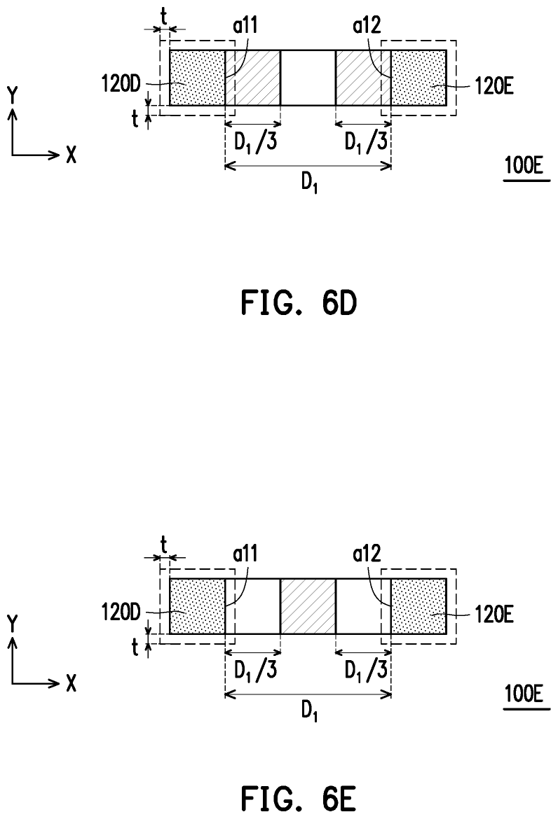

Next, the present embodiment uses a chip package structure with two chips, such as the chip package structure 100E in the region R2 in FIG. 3, for the description of position arrangement of the transistor 112. FIG. 6A is a schematic diagram of orthogonal projections of two chips on a first surface S1 of an encapsulation material 130 away from a redistribution circuit layer 110. An orthogonal projection of the first chip on the first surface S1 is a first projection 120D, and an orthogonal projection of a second chip on the first surface S1 is a second projection 120E. The first projection 120D has an edge a11 close to the second projection 120E, the second projection 120E has an edge a12 close to the first projection 120D, and a distance between a center of the edge a11 and a center of the edge a12 is D₁. In an arrangement direction parallel to the first projection 120D and the second projection 120E (X-direction), a position of an orthogonal projection of the transistor 112 arranged in the redistribution circuit layer 110 on the first surface S1 meets one of the following conditions (1) and (2):

condition (1): between the edge a11 and the D₁/3 position from the edge a11, and

condition (2): between the D₁/3 position from the edge a11 and a 2D₁/3 position from the edge a11.

If the position of the orthogonal projection of the transistor 112 on the first surface S1 meets the condition (1), the position of the orthogonal projection of the transistor 112 on the first surface S1 may alternatively be simultaneously between the edge a12 and the D₁/3 position from the edge a12.

The condition (2) may alternatively be expressed as: the position of the orthogonal projection of the transistor 112 on the first surface S1 may be between the D₁/3 position from the edge a12 and the 2D₁/3 position from the edge a12.

In addition, in an arrangement direction perpendicular to the first projection 120D and the second projection 120E (Y-direction), the position of the orthogonal projection of the transistor 112 arranged in the redistribution circuit layer 110 on the first surface S1 is between lines 11 and 12 of two end points corresponding to the edge a11 and the edge a12.

The disclosure subsequently uses embodiments for describing the case that positions of chips in the chip package structure with two chips are taken as references for arrangement of the transistor in the redistribution circuit layer.

FIG. 6B is a top view of an arrangement position of a transistor 112 in a chip package structure according to a sixth embodiment of the disclosure. The sixth embodiment in FIG. 6B meets the condition (1), and a position of an orthogonal projection of the transistor 112 on a first surface S1 may be between the edge a11 and D₁/3 position from the edge a11 or between the edge a12 and the D₁/3 position from the edge a12, or may be simultaneously between the edge a11 and the D₁/3 position from the edge a11 and between the edge a12 and the D₁/3 position from the edge a12.

FIG. 6C is a top view of an arrangement position of a transistor 112 in a chip package structure according to a seventh embodiment of the disclosure. The seventh embodiment in FIG. 6C meets the condition (2), and a position of an orthogonal projection of the transistor 112 on a first surface S1 may be between the D₁/3 position from the edge a11 and the 2D₁/3 position from the edge a11. In other words, the position of the orthogonal projection of the transistor 112 on the first surface S1 can be between the D₁/3 position from the edge a12 and the 2D₁/3 position from the edge a12.

FIG. 6D is a top view of an arrangement position of a transistor 112 in a chip package structure according to an eighth embodiment of the disclosure. For the eighth embodiment in FIG. 6D, refer to the fifth embodiment in FIG. 5 and the sixth embodiment in FIG. 6B. In the eighth embodiment in FIG. 6D, a position of an orthogonal projection of the transistor 112 on a first surface S1 may be as those illustrated in the fifth embodiment in FIG. 5 and the sixth embodiment in FIG. 6B.

FIG. 6E is a top view of an arrangement position of a transistor 112 in a chip package structure according to a ninth embodiment of the disclosure. For the ninth embodiment in FIG. 6E, refer to the fifth embodiment in FIG. 5 and the seventh embodiment in FIG. 6C. In the ninth embodiment in FIG. 6E, a position of an orthogonal projection of the transistor 112 on a first surface S1 may be as those illustrated in the fifth embodiment in FIG. 5 and the seventh embodiment in FIG. 6C.

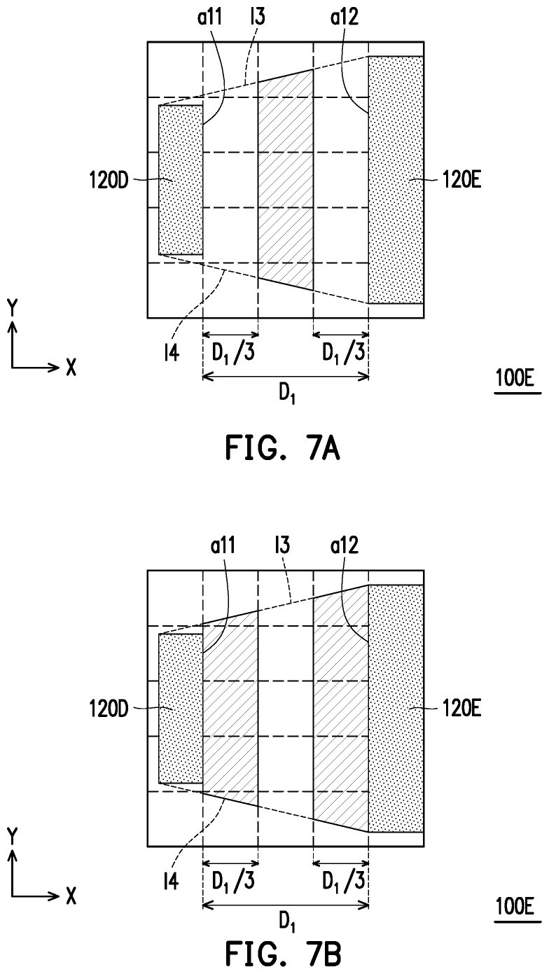

FIG. 7A and FIG. 7B are respectively top views of arrangement positions of transistors 112 in chip package structures according to a tenth embodiment and an eleventh embodiment of the disclosure. These embodiments still use the chip package structure with two chips for the description of position arrangement of the transistor 112. For components of the chip package structures 100E in FIG. 7A and FIG. 7B, refer to the chip package structures 100A and 100B in FIG. 1 and FIG. 2, and details are not described herein. The chip package structures 100E in FIG. 7A and FIG. 7B are similar to the chip package structure 100E in FIG. 6A, but the first projection 120D and the second projection 120E are different in size; and the same components as those in FIG. 6A are not described again. The first projection 120D and the second projection 120E respectively have an edge a11 and an edge a12 which are close to each other but different in length, a distance between a center of the edge a11 and a center of the edge a12 is D₁, and an orthogonal projection of a transistor 112 on a first surface S1 is within the scope of a quadrangle formed by the edge a11, the edge a12 and two external common tangents 13 and 14 of the first projection 120D and the second projection 120E. In an arrangement direction parallel to the first projection 120D and the second projection 120E (X-direction), the position of the orthogonal projection of the transistor 112 on the first surface S1 meets one of the conditions (1) and (2) as those illustrated in FIG. 6A (referring to the sixth embodiment in FIG. 6B to the ninth embodiment in FIG. 6E).

In addition, each of positions of the first chip and the second chip may be respectively taken as a reference for arrangement of the transistor 112. Refer to the description of the fifth embodiment in FIG. 5, and details are not described herein.

Referring to FIG. 7A, a position of an orthogonal projection of a transistor 112 on a first surface S1 in the present embodiment meets the condition (2). In other words, in an arrangement direction parallel to a first projection 120D and a second projection 120E (X-direction), the position of the orthogonal projection of the transistor 112 on the first surface S1 may be between the D₁/3 position from the edge a11 and the 2D₁/3 position from the edge a11. In other words, the position of the orthogonal projection of the transistor 112 on the first surface S1 may be between the D₁/3 position from the edge a12 and the 2D₁/3 position from the edge a12. In an arrangement direction perpendicular to the first projection 120D and the second projection 120E (Y-direction), the position of the orthogonal projection of the transistor 112 on the first surface S1 is within the scope of two external common tangents 13 and 14 of the first projection 120D and the second projection 120E.

Referring to FIG. 7B, a position of an orthogonal projection of a transistor 112 on a first surface S1 in the present embodiment meets the condition (1). In other words, in an arrangement direction parallel to a first projection 120D and a second projection 120E (X-direction), the position of the orthogonal projection of the transistor 112 on the first surface S1 may be simultaneously between the edge a11 and the D₁/3 position from the edge a11 and between the edge a12 and the D₁/3 position from the edge a12. In an arrangement direction perpendicular to the first projection 120D and the second projection 120E (Y-direction), the position of the orthogonal projection of the transistor 112 on the first surface S1 is within the scope of two external common tangents 13 and 14 of the first projection 120D and the second projection 120E.

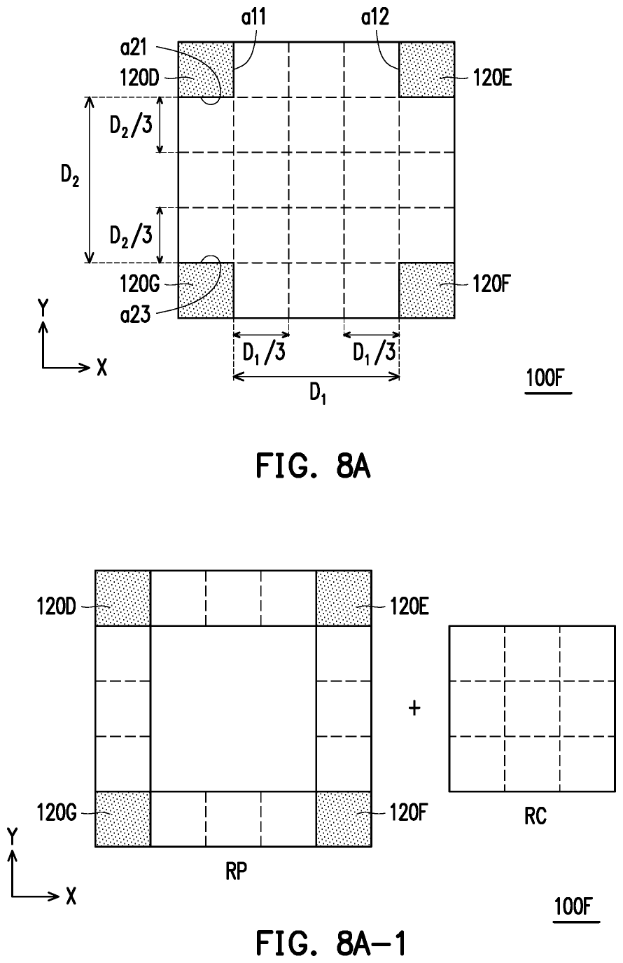

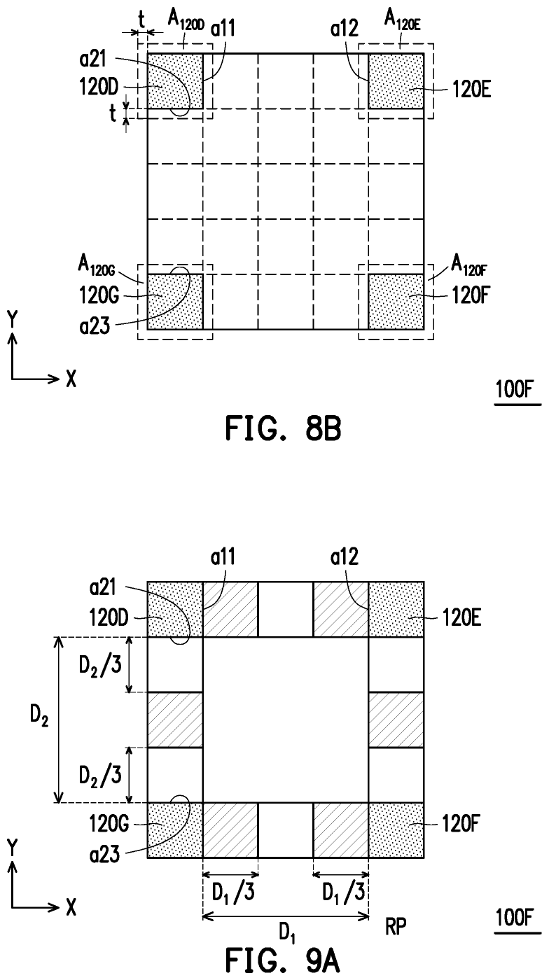

Next, the description of position arrangement of a transistor in a chip package structure with four chips is provided, referring to FIG. 3 and FIG. 8A. The chip package structure with four chips is as shown in the chip package structure 100F in the region R3 in FIG. 3, and for a package structure of each chip, reference may be made to 100A in FIG. 1, and details are not described herein. FIG. 8A is a schematic diagram of orthogonal projections of four chips on a first surface S1 of an encapsulation material 130 away from a redistribution circuit layer 110. An orthogonal projection of the first chip on the first surface S1 is a first projection 120D, an orthogonal projection of a second chip on the first surface S1 is a second projection 120E, an orthogonal projection of a third chip on the first surface S1 is a third projection 120F, and an orthogonal projection of a fourth chip on the first surface S1 is a fourth projection 120G. The first projection 120D, the second projection 120E, the third projection 120F and the fourth projection 120G are arranged in a matrix, the first projection 120D and the third projection 120F are arranged diagonally, and the second projection 120E and the fourth projection 120G are arranged diagonally. The first projection 120D and the second projection 120E respectively have an edge a11 and an edge a12 close to each other, and the first projection 120D and the fourth projection 120G respectively have an edge a21 and an edge a23 close to each other. A distance between a center of the edge a11 and a center of the edge a12 is D₁, and a distance between a center of the edge a21 and a center of the edge a23 is D₂, where D₁ and D₂ may be the same or different.

For convenience of description, the schematic diagram of the orthogonal projections of the four chips in FIG. 8A is divided into a central region RC and peripheral regions RP as shown in FIG. 8A-1. FIG. 8A-1 is a schematic diagram for dividing the schematic diagram of the orthogonal projections of the four chips in FIG. 8A into the central region RC and the peripheral regions RP. In the chip package structure with four chips, an arrangement position of a transistor 112 may be illustrated by any one of the four chips, the central region RC and the peripheral regions RP. In this embodiment, the first projection 120D, the second projection 120E, the third projection 120F, and the fourth projection 120G are the same in size. However, in other embodiments, at least two of the first projection 120D, the second projection 120E, the third projection 120F, and the fourth projection 120G may be different in size.

FIG. 8B is a top view of an arrangement position of a transistor 112 in a chip package structure according to a twelfth embodiment of the disclosure. Referring to FIG. 5, FIG. 8A and

FIG. 8B, the chip package structure 100F in FIG. 8B has four chips of the same arrangement as that in FIG. 8A, and each chip may be independently taken as a reference for position arrangement of the transistor 112 in a redistribution circuit layer 110, as illustrated in the fifth embodiment in FIG. 5. In other words, the position of the orthogonal projection of the transistor 112 in a direction perpendicular to the first surface S1 may be within the scope of quadrangles A_{120D}, A_{120E}, A_{120F} and A_{120G} surrounded by dotted lines in FIG. 8B. A relationship between the quadrangles A_{120D}, A_{120E}, A_{120F} and A_{120G} and the first projection 120D, the second projection 120E, the third projection 120F and the fourth projection 120G is illustrated with reference to the rectangle A and the quadrangle B in FIG. 5.

Next, the description of arrangement of transistors 112 in the peripheral regions RP in FIG. 8A-1 is provided, referring to FIG. 8A and FIG. 8A-1. FIG. 8A is the schematic diagram of orthogonal projections of four chips on the first surface S1 of an encapsulation material 130 away from the redistribution circuit layer 110. Positions of a pair of adjacent chips in the four chips in FIG. 8A may be taken as references for the arrangement of the transistor 112, and four pairs of adjacent chips of the four chips arranged in a matrix may be respectively taken as references for position arrangement of the transistor 112. For example, positions of the first chip and the second chip, the first chip and the fourth chip, the second chip and the third chip or the third chip and the fourth chip are taken as references for the arrangement of the transistor 112, as shown in the peripheral regions RP in FIG. 8A-1. Any pair of adjacent chips in the peripheral regions RP are taken as references for the arrangement of the position of the transistor 112, and the description is as shown in the sixth embodiment in FIG. 6A to the ninth embodiment in FIG. 6E and is not described herein. A distance between a center of an edge a11 and a center of an edge a12 is D₁, a distance between a center of an edge a21 and a center of an edge a23 is D₂, and D₁ and D₂ may be the same or different. In addition, in an arrangement direction parallel to a first projection 120D and a second projection 120E (X-direction) or in an arrangement direction parallel to the first projection 120D and a fourth projection 120G (Y-direction), arrangement modes of transistors 112 may be the same or different. The embodiments of the disclosure do not limit the arrangement modes of the transistors 112 in two different directions.

The adjacent first chip and second chip and the adjacent first chip and fourth chip are taken as a pair of chips respectively for the description of the arrangement position of the transistor 112. The description of the arrangement position of the transistor 112 may be similarly deduced by taking the adjacent second chip and third chip and the adjacent third chip and fourth chip as a pair of chips respectively, and details are not described herein.

Next, embodiments are provided for describing the case that positions of chips in a chip package structure with four chips arranged in a matrix are taken as references for arrangement of transistors 112 in a redistribution circuit layer 110 in the peripheral regions RP.

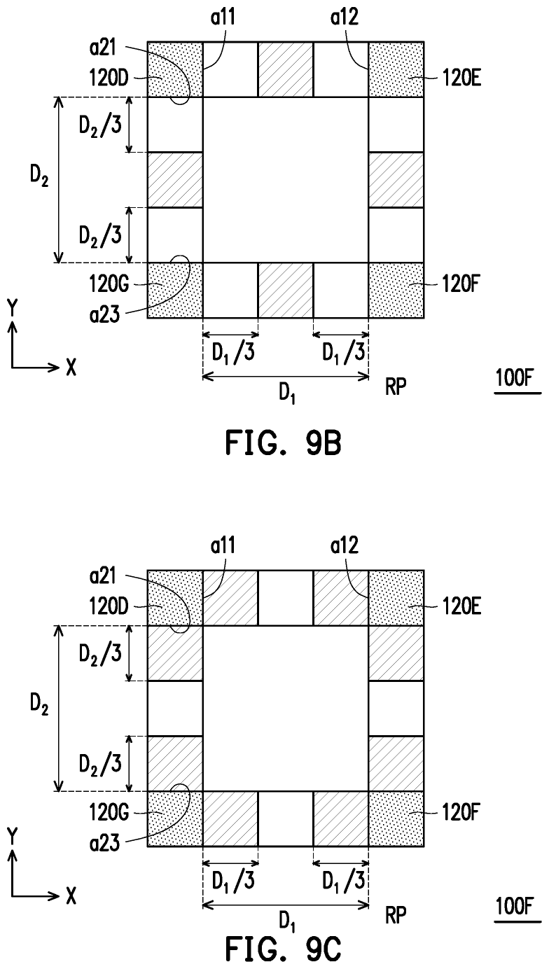

FIG. 9A to FIG. 9C are respectively top views of arrangement positions of transistors 112 in peripheral regions RP of chip package structures according to a thirteenth embodiment to a fifteenth embodiment of the disclosure.

In the thirteenth embodiment in FIG. 9A, a transistor 112 taking two chips arranged along an X-direction in the peripheral regions RP as references for position arrangement meets the arrangement mode of the condition (1), and a transistor 112 taking two chips arranged along a Y-direction in the peripheral regions RP as references for position arrangement meets the arrangement mode of the condition (2) in the above embodiment.

In the fourteenth embodiment in FIG. 9B, a transistor 112 taking two chips arranged in an X-direction in the peripheral regions RP as references for position arrangement meets the arrangement mode of the condition (2), and a transistor 112 taking two chips arranged along a Y-direction in the peripheral regions RP as references for position arrangement meets the arrangement mode of the condition (2) in the above embodiment.

In the fifteenth embodiment in FIG. 9C, a transistor 112 taking two chips arranged in an X-direction in the peripheral regions RP as references for position arrangement meets the arrangement mode of the condition (1), and a transistor 112 taking two chips arranged along a Y-direction in the peripheral regions RP as references for position arrangement meets the arrangement mode of the condition (1) in the above embodiment.

Next, for the description of arrangement of a transistor 112 in the central region RC in FIG. 8A-1, refer to FIG. 8A and FIG. 8A-1. In an arrangement direction parallel to a first projection 120D and a second projection 120E (X-direction), a position of an orthogonal projection of the transistor 112 on a first surface S1 meets one of the following conditions (i) and (ii):

condition (i): between an edge a11 and the D₁/3 position from the edge a11, and

condition (ii): between the D₁/3 position from the edge a11 and the 2D₁/3 position from the edge a11.

Furthermore, in an arrangement direction parallel to the first projection 120D and a fourth projection 120G (Y-direction), the position of the orthogonal projection of the transistor 112 on the first surface S1 meets one of the following conditions (a) and (b):

condition (a): between an edge a21 and the D₂/3 position from the edge a21, and

condition (b): between the D₂/3 position from the edge a21 and the 2D₂/3 position from the edge a21.

If the position of the orthogonal projection of the transistor 112 on the first surface S1 meets the condition (i), the position of the orthogonal projection of the transistor 112 on the first surface S1 may be simultaneously between the edge a12 and the D₁/3 position from the edge a12. Similarly, if the position of the orthogonal projection of the transistor 112 on the first surface S1 meets the condition (a), the position of the orthogonal projection of the transistor 112 on the first surface S1 may be simultaneously between the edge a23 and the D₂/3 position from the edge a23.

The position of the orthogonal projection of the transistor 112 on the first surface S1 meets the condition (ii), in other words, the position of the orthogonal projection of the transistor 112 on the first surface S1 may be between the D₁/3 position from the edge a12 and the 2D₁/3 position from the edge a12. The position of the orthogonal projection of the transistor 112 on the first surface S1 meets the condition (b), in other words, the position of the orthogonal projection of the transistor 112 on the first surface S1 may be between the D₂/3 position from the edge a23 and the 2D₂/3 position from the edge a23.

Next, embodiments are provided for describing the case that positions of chips in a chip package structure with four chips arranged in a matrix are taken as references for arrangement of the transistor 112 in the redistribution circuit layer 110 in the central regions RC.

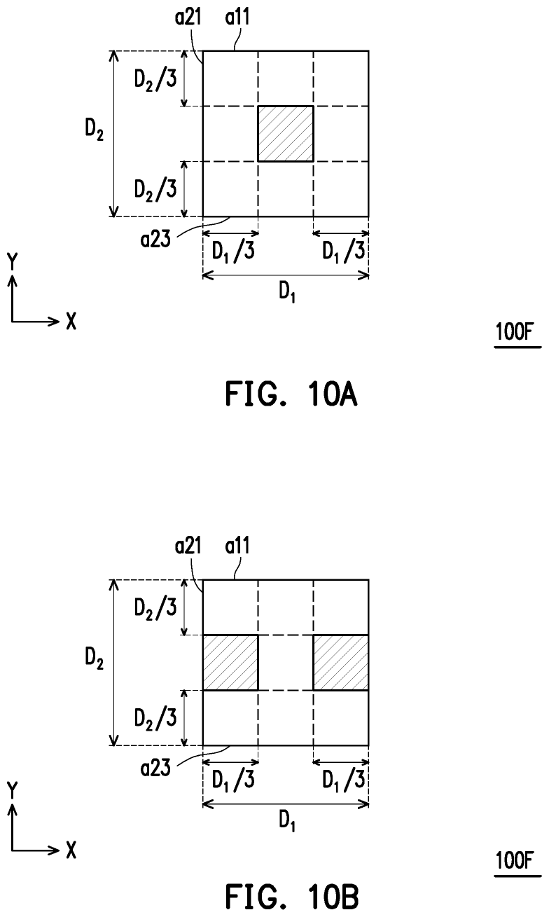

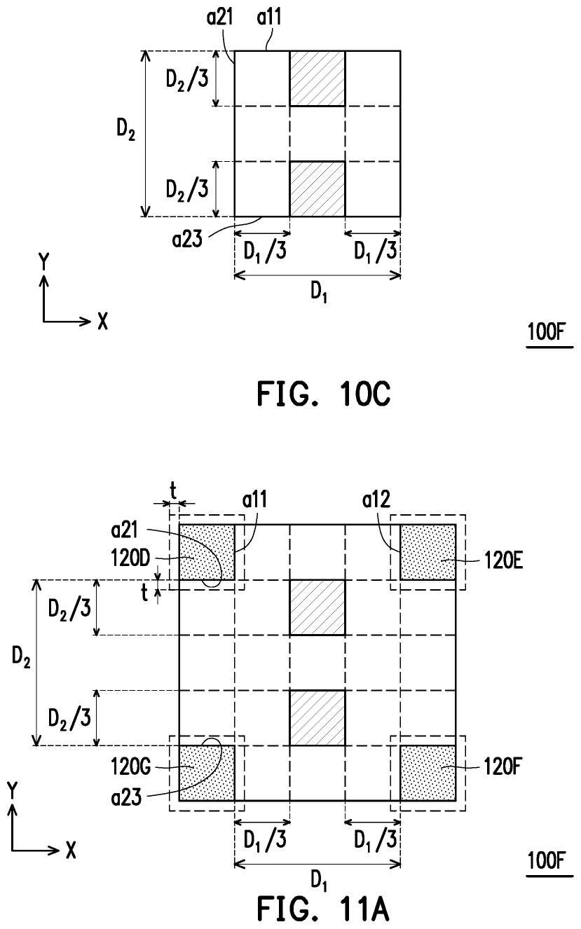

FIG. 10A to FIG. 10C are respectively top views of arrangement positions of transistors 112 in central regions RC of chip package structures according to a sixteenth embodiment to an eighteenth embodiment of the disclosure.

The sixteenth embodiment in FIG. 10A is a schematic diagram of an arrangement position of a transistor 112 meeting the condition (ii) and the condition (b).

The seventeenth embodiment in FIG. 10B is a schematic diagram of an arrangement position of a transistor 112 meeting the condition (i) and the condition (b).

The eighteenth embodiment in FIG. 10C is a schematic diagram of an arrangement position of a transistor 112 meeting the condition (ii) and the condition (a).

Next, embodiments are provided for describing the case that positions of chips in a chip package structure with four chips arranged in a matrix are taken as references for simultaneous arrangement of transistors 112 in a redistribution circuit layer 110 in a central region RC and peripheral regions RP.

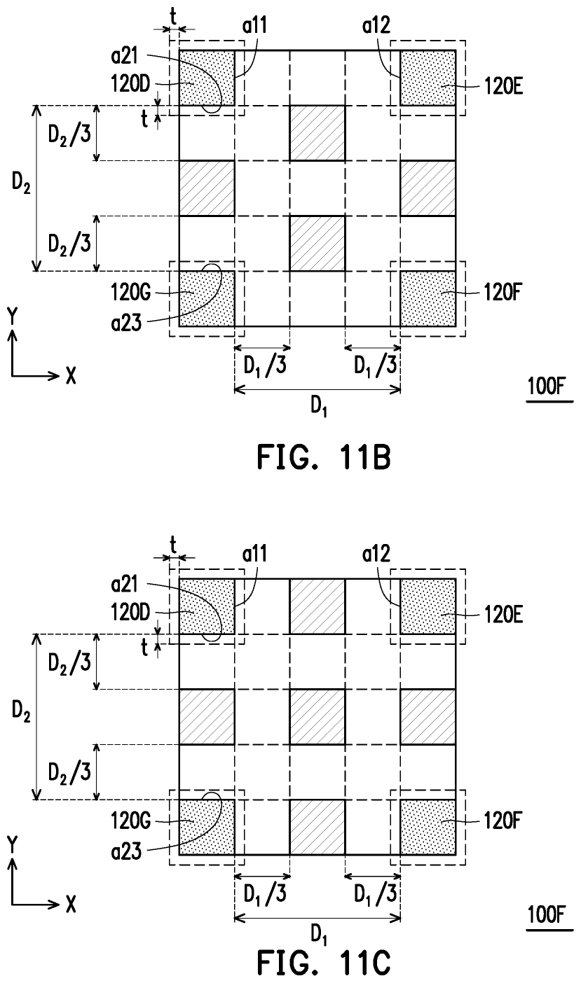

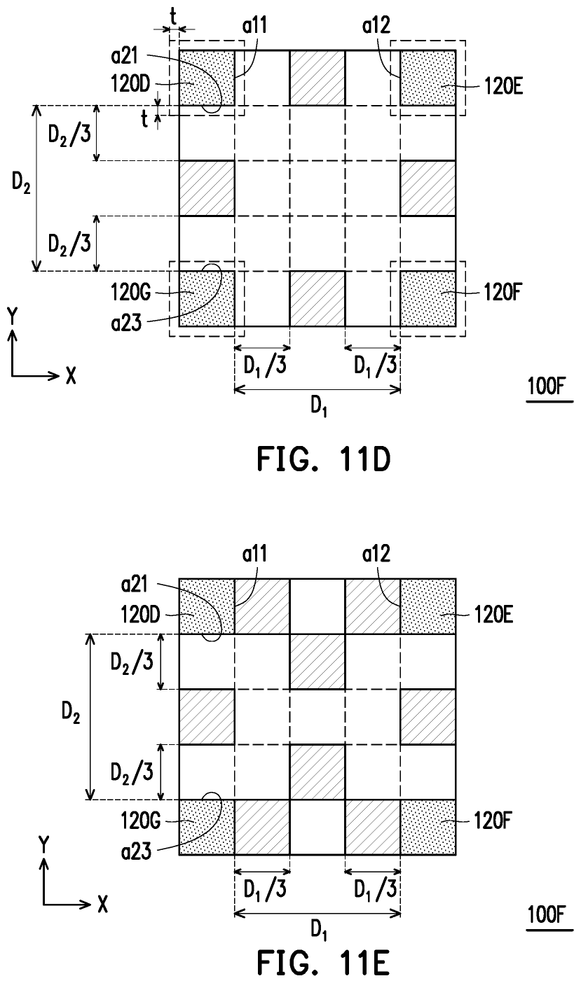

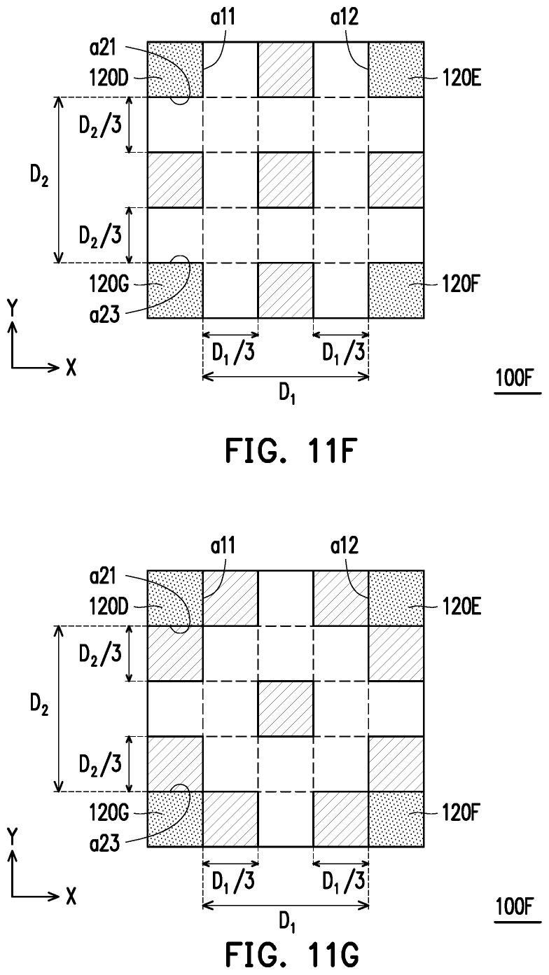

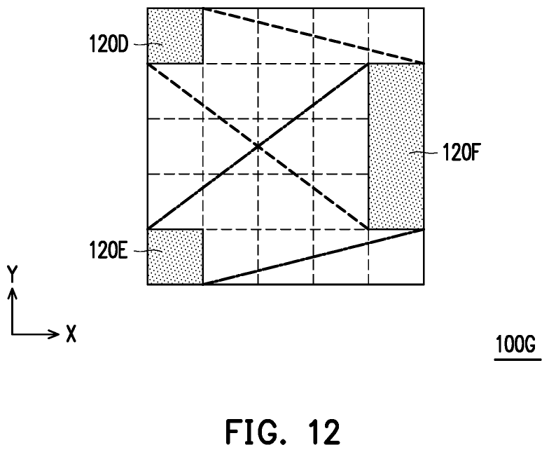

FIG. 11A to FIG. 11G are respectively top views of arrangement positions of transistors 112 in chip package structures according to a nineteenth embodiment to a twenty-fifth embodiment of the disclosure.

Referring to FIG. 11A, for arrangement of a transistor 112 according to the nineteenth embodiment in FIG. 11A, refer to the arrangement of the transistors 112 according to the twelfth embodiment in FIG. 8B and the eighteenth embodiment (central region RC) in FIG. 10C.

Referring to FIG. 11B, for arrangement of a transistor 112 according to the twentieth embodiment in FIG. 11B, refer to the arrangement of the transistor 112 according to the twelfth embodiment in FIG. 8B, the arrangement of the transistors meeting the condition (2) along the Y-direction in the peripheral regions RP and the arrangement of the transistor 112 in the central region RC according to the eighteenth embodiment in FIG. 10C.

Referring to FIG. 11C, for arrangement of transistor 112 according to the twenty-first embodiment in FIG. 11C, refer to the arrangement of the transistor 112 according to the twelfth embodiment in FIG. 8B, the arrangement of the transistors 112 according to the fourteenth embodiment (peripheral regions RP) in FIG. 9B and the arrangement of the transistor 112 according to the sixteenth embodiment (central region RC) in FIG. 10A.

Referring to FIG. 11D, for arrangement of transistor 112 according to the twenty-second embodiment in FIG. 11D, refer to the arrangement of the transistors 112 according to the twelfth embodiment in FIG. 8B and the fourteenth embodiment (peripheral regions RP) in FIG. 9B.

Referring to FIG. 11E, for arrangement of transistor 112 according to the twenty-third embodiment in FIG. 11E, refer to the arrangement of the transistors 112 according to the thirteenth embodiment (peripheral regions RP) in FIG. 9A and the eighteenth embodiment (central region RC) in FIG. 10C.

Referring to FIG. 11F, for arrangement of a transistor 112 according to the twenty-fourth embodiment in FIG. 11F, refer to the arrangement of the transistors 112 according to the fourteenth embodiment (peripheral regions RP) in FIG. 9B and the sixteenth embodiment (central region RC) in FIG. 10A.

Referring to FIG. 11G, for arrangement of a transistor 112 according to the twenty-fifth embodiment in FIG. 11G, refer to the arrangement of the transistors 112 according to the fifteenth embodiment (peripheral regions RP) in FIG. 9C and the sixteenth embodiment (central region RC) in FIG. 10A.

The above embodiments of the disclosure at most take four chips in a chip package structure for the description of arrangement of a transistor, but the disclosure is not limited thereto. Different numbers (greater than four) of chips may be combined referring to the description of the single chip, the two chips and the four chips according to the above embodiments so as to obtain proper position arrangement of a transistor in a redistribution circuit layer.

FIG. 12 is a top view of an arrangement position of a transistor 112 in a chip package structure according to a twenty-sixth embodiment of the disclosure. In the twenty-sixth embodiment in FIG. 12, the chip package structure 100G has three chips. An orthogonal projection of a first chip on a first surface S1 is a first projection 120D, an orthogonal projection of a second chip on the first surface S1 is a second projection 120E, and an orthogonal projection of a third chip on the first surface S1 is a third projection 120F. Centers of the first projection 120D, the second projection 120E and the third projection 120F of the present embodiment form a triangle, and sizes of the orthogonal projections of the three chips on the first surface S1 may be the same or different.

The twenty-sixth embodiment in FIG. 12 may respectively take two of the three chips as references for position arrangement of the transistor 112. For example, the first chip and the second chip, the second chip and the third chip or the third chip and the first chip may be respectively taken as references for position arrangement of the transistor 112, and the proper position of the transistor 112 may be any one or any combination of the three situations.

Referring to the twenty-sixth embodiment in FIG. 12, arrangement modes of the first projection 120D and the second projection 120E are as shown in FIG. 6. If the positions of the first chip and the second chip are taken as references for position arrangement of the transistor 112, for the position of the transistor 112 in the redistribution circuit layer 110, reference may be made to the description of the fifth embodiment in FIG. 5 and the sixth embodiment in FIG. 6A to the ninth embodiment in FIG. 6E, and details are not described herein.

In the twenty-sixth embodiment in FIG. 12, the arrangement modes of the first projection 120D and the third projection 120F or the second projection 120E and the third projection 120F are similar to those shown in FIG. 7A and FIG. 7B. If the positions of the first chip and the third chip or the second chip and the third chip are taken as references for position arrangement of the transistor 112, for the position of the transistor 112 in the redistribution circuit layer 110, reference may be made to the description of the fifth embodiment in FIG. 5 and the tenth embodiment in FIG. 7A to the eleventh embodiment in FIG. 7B, and details are not described herein.

Based on the above, the embodiments of the disclosure provide a chip package structure, transistors are arranged in a redistribution circuit layer of the chip package structure, and arrangement positions of the transistors can enable the transistors to be subjected to a relatively small stress after support substrates are removed so as to maintain functions of the transistors.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A chip package structure, comprising:
a redistribution circuit layer, comprising at least one transistor;
a first chip and a second chip, arranged on the redistribution circuit layer and being electrically connected to the redistribution circuit layer; and
an encapsulation material, arranged on the redistribution circuit layer, comprising a first surface away from the redistribution circuit layer and covering the first chip and the second chip, wherein orthogonal projections of the first chip and the second chip on the first surface are respectively a first projection and a second projection, the first projection and the second projection respectively comprise an edge a11 and an edge a12 close to each other, and a distance between a center of the edge a11 and a center of the edge a12 is D₁,
wherein a position of an orthogonal projection of the at least one transistor on the first surface meets one of the following conditions (1) and (2):
condition (1): between the edge a11 and a D₁/3 position from the edge a11, and
condition (2): between the D₁/3 position from the edge a11 and a 2D₁/3 position from the edge a11.

2. The chip package structure according to claim 1, wherein if the condition (1) is met, the position of the orthogonal projection of the at least one transistor on the first surface is further between the edge a12 and the D₁/3 position from the edge a12.

3. The chip package structure according to claim 1, wherein the orthogonal projection of the at least one transistor on the first surface is within a scope of a quadrangle formed by the edge a11, the edge a12 and two external common tangents of the first projection and the second projection.

4. The chip package structure according to claim 1, further comprising a third chip and a fourth chip which are arranged on the redistribution circuit layer together with the first chip and the second chip in an array arrangement mode, wherein the first chip and the third chip are arranged diagonally, the encapsulation material covers the third chip and the fourth chip, orthogonal projections of the third chip and the fourth chip on the first surface are respectively a third projection and a fourth projection, the first projection and the fourth projection respectively comprise an edge a21 and an edge a23 close to each other, and a distance between a center of the edge a21 and a center of the edge a23 is D₂,
wherein in an arrangement direction parallel to the first projection and the second projection, the position of the orthogonal projection of the at least one transistor on the first surface meets one of the following conditions (i) and (ii):
condition (i): between the edge a11 and the D₁/3 position from the edge a11, and
condition (ii): between the D₁/3 position from the edge a11 and the 2D₁/3 position from the edge a11; and
in an arrangement direction parallel to the first projection and the fourth projection, the position of the orthogonal projection of the at least one transistor on the first surface meets one of the following conditions (a) and (b):
condition (a): between the edge a21 and a D₂/3 position from the edge a21, and condition (b): between the D₂/3 position from the edge a21 and the 2D₂/3 position from the edge a21.

5. The chip package structure according to claim 4, wherein if the condition (i) is met, the position of the orthogonal projection of the at least one transistor on the first surface is further between the edge a12 and a D₁/3 position from the edge a12.

6. The chip package structure according to claim 4, wherein if the condition (a) is met, the position of the orthogonal projection of the at least one transistor on the first surface is further between the edge a23 and a D₂/3 position from the edge a23.

7. The chip package structure according to claim 4, wherein at least two of the first projection, the second projection, the third projection, and the fourth projection are different in size.

8. The chip package structure according to claim 1, wherein the redistribution circuit layer further comprises at least one redistribution circuit, the at least one redistribution circuit is electrically connected to the at least one transistor, the at least one redistribution circuit comprises a voltage source circuit and a ground circuit, and the at least one transistor is electrically connected to the voltage source circuit, the ground circuit and a pin end of the first chip or the second chip.

9. The chip package structure according to claim 1, wherein the at least one transistor comprises a thin film transistor.

10. The chip package structure according to claim 1, wherein the encapsulation material comprises epoxy resin.

11. The chip package structure according to claim 1, wherein the redistribution circuit layer further comprises a plurality of dielectric layers, and the at least one transistor is positioned in one of the plurality of dielectric layers.

12. The chip package structure according to claim 1 further comprising a third chip arranged on the redistribution circuit layer, wherein the first chip and the second chip are arranged in a direction, and the first chip and the third chip are arranged in another direction, an orthogonal projection of the third chip on the first surface is a third projection; the first projection and the third projection respectively comprise an edge a21 and an edge a23 close to each other, and a distance between a center of the edge a21 and a center of the edge a23 is D₂,
wherein a position of an orthogonal projection of the at least one transistor on the first surface also meets one of the following conditions (a) and (b):
condition (a): between the edge a21 and a D₂/3 position from the edge a21, and
condition (b): between the D₂/3 position from the edge a21 and the 2D₂/3 position from the edge a21.

13. A chip package structure, comprising:
a redistribution circuit layer, comprising at least one transistor;
a first chip, arranged on the redistribution circuit layer and being electrically connected to the redistribution circuit layer; and
an encapsulation material, arranged on the redistribution circuit layer, comprising a first surface away from the redistribution circuit layer and covering the first chip, wherein a thickness of the first chip in a direction perpendicular to the first surface is t, an orthogonal projection of the first chip on the first surface comprises four edges, and the four edges form a rectangle with an area A,
wherein a position of an orthogonal projection of the at least one transistor on the first surface is within a quadrangle surrounded by four straight lines respectively parallel to the four edges and with a distance t from the four edges, and the area of the quadrangle is greater than the area A.

14. The chip package structure according to claim 13, wherein the redistribution circuit layer further comprises at least one redistribution circuit, the at least one redistribution circuit is electrically connected to the at least one transistor, the at least one redistribution circuit comprises a voltage source circuit and a ground circuit, and the at least one transistor is electrically connected to the voltage source circuit, the ground circuit and a pin end of the first chip.

15. The chip package structure according to claim 13 further comprising a second chip arranged on the redistribution circuit layer and being electrically connected to the redistribution circuit layer, wherein orthogonal projections of the first chip and the second chip on the first surface are respectively a first projection and a second projection, the first projection and the second projection respectively comprise an edge a11 and an edge a12 close to each other, and a distance between a center of the edge a11 and a center of the edge a12 is D₁,
wherein a position of an orthogonal projection of the at least one transistor on the first surface meets one of the following conditions (1) and (2):
condition (1): between the edge a11 and a D₁/3 position from the edge a11, and
condition (2): between the D₁/3 position from the edge a11 and a 2D₁/3 position from the edge a11.

16. A chip package structure, comprising:
a redistribution circuit layer, comprising at least one transistor;
a first chip, a second chip, a third chip and a fourth chip, arranged on the redistribution circuit layer in an array arrangement mode and are electrically connected to the redistribution circuit layer, wherein the first chip and the third chip are arranged diagonally; and
an encapsulation material, arranged on the redistribution circuit layer, comprising a first surface away from the redistribution circuit layer and covering the first chip, the second chip, the third chip and the fourth chip, wherein orthogonal projections of the first chip, the second chip, the third chip and the fourth chip on the first surface are respectively a first projection, a second projection, a third projection and a fourth projection, the first projection and the second projection respectively comprise an edge a11 and an edge a12 close to each other, a distance between a center of the edge a11 and a center of the edge a12 is D₁, the first projection and the fourth projection respectively comprise an edge a21 and an edge a23 close to each other, and a distance between a center of the edge a21 and a center of the edge a23 is D₂,
wherein in an arrangement direction parallel to the first projection and the second projection, a position of an orthogonal projection of the at least one transistor on the first surface meets one of the following conditions (i) and (ii):
condition (i): between the edge a11 and a D₁/3 position from the edge a11, and
condition (ii): between the D₁/3 position from the edge a11 and a 2D₁/3 position from the edge a11; and
in an arrangement direction parallel to the first projection and the fourth projection, the position of the orthogonal projection of the at least one transistor on the first surface meets one of the following conditions (a) and (b):
condition (a): between the edge a21 and a D₂/3 position from the edge a21, and
condition (b): between the D₂/3 position from the edge a21 and a 2D₂/3 position from the edge a21.

17. The chip package structure according to claim 16, wherein if the condition (i) is met, the position of the orthogonal projection of the at least one transistor on the first surface is further between the edge a12 and a D₁/3 position from the edge a12.

18. The chip package structure according to claim 16, wherein if the condition (a) is met, the position of the orthogonal projection of the at least one transistor on the first surface is further between the edge a23 and the D₂/3 position from the edge a23.

19. The chip package structure according to claim 16, wherein at least two of the first projection, the second projection, the third projection, and the fourth projection are different in size.

20. The chip package structure according to claim 16, wherein the redistribution circuit layer further comprises at least one redistribution circuit, the at least one redistribution circuit is electrically connected to the at least one transistor, the at least one redistribution circuit comprises a voltage source circuit and a ground circuit, and the at least one transistor is electrically connected to the voltage source circuit, the ground circuit and a pin end of at least one of the first chip, the second chip, the third chip and the fourth chip.
